(19) United States
(12) Patent Application Publication
(10) Pub. No.: US 2026/0280586 A1
(43) Pub. Date: Sep. 17, 2026

(54) RANKED SUCCESSIVE DETECTION AND DECODING METHOD AND RECEIVER BASED ON SPARSE CODE MULTIPLE ACCESS

(71) Applicant: Guangdong University of Technology, Guangzhou (CN)

(72) Inventors: Yi FANG, Guangzhou (CN); Yunye LI, Guangzhou (CN); Zhaojie YANG, Guangzhou (CN); Liang LYU, Guangzhou (CN); Guojun HAN, Guangzhou (CN)

(21) Appl. No.: 19/669,196

(22) Filed: May 6, 2026

(30) Foreign Application Priority Data
Aug. 29, 2025 (CN) 202511229384.9

(51) Int. Cl. H03M 13/11

(52) U.S. Cl. CPC H03M 13/1128; H03M 13/1125

(57) ABSTRACT

A ranked successive detection and decoding (R-SDD) method based on Sparse Code Multiple Access (SCMA) includes following steps: external iterations are performed successively according to an initial confidence order based on received signals of a plurality of users and initialized posteriori log-likelihood ratios; an external iteration count is updated; decoding verification is performed on output first posteriori log-likelihood ratios; if there is an unsuccessfully decoded user and the external iteration count has not reached a threshold, a next external iteration is performed successively according to the received signal and a first priori log-likelihood ratio of each unsuccessfully decoded user; the external iteration count is updated; decoding verification is performed based on output second posteriori log-likelihood ratios; and when it is determined that there is no unsuccessfully decoded user or the external iteration count reaches the threshold, a decoded bit sequence is output. A R-SDD receiver is also provided.

### CROSS-REFERENCE TO RELATED APPLICATIONS

This application claims the benefit of priority from Chinese Patent Application No. 202511229384.9, filed on Aug. 29, 2025. The content of the aforementioned application, including any intervening amendments made thereto, is incorporated herein by reference in its entirety.

### TECHNICAL FIELD

This application relates to communication technology, and more particularly to a ranked successive detection and decoding (R-SDD) method and receiver based on sparse code multiple access (SCMA).

### BACKGROUND

With the rapid development of mobile communication technology, user demand for wireless communication with high rates, massive connectivity, and low latency is increasingly growing. Non-orthogonal multiple access (NOMA) technology is gradually becoming a key enabler for future sixth generation (6G) mobile communication systems due to its ability to support higher throughput. Among various NOMA schemes, SCMA technology allows multiple users to share limited frequency-domain or time-domain resources and has attracted widespread attention due to its high spectral efficiency, greater channel capacity, and excellent error correction performance.

Existing SCMA technologies typically employ iterative detection and decoding (IDD) receivers, which allow the detector to utilize soft information output from the decoder, thereby effectively eliminating inter-user interference. Conventional IDD receivers typically employ a combination of a SCMA detector and a channel decoder to complete decoding through multiple rounds of external iteration. However, parallel deployment of channel decoders prevents users from sharing soft information within the current iteration round, preventing users with poor channel quality from efficiently utilizing the soft information from other users after decoding to improve their own decoding. Furthermore, all users are required to perform a complete detection and decoding operation in each iteration. Users who have already successfully decoded in previous iterations still need to repeat the computations, resulting in wasted computational resources and increased system complexity and power consumption. Additionally, computational resources cannot be flexibly allocated and scheduled based on actual channel conditions, and the number of required decoders must be an integer multiple of the number of users, which limits flexible deployment in specific hardware implementations. Therefore, there is an urgent need to improve receiver performance of SCMA systems under limited complexity.

### SUMMARY

In view of the deficiencies in the prior art, this application provides a R-SDD method and receiver based on SCMA to improve receiver performance of an SCMA system under existing limited complexity.

Technical solutions of the present disclosure are described as follows.

In a first aspect, this application provides a R-SDD method based on SCMA, comprising:
in response to receiving a received signal superimposed by transmissions from a plurality of users, successively performing, based on the received signal and an initialized posteriori log-likelihood ratio of each user, message passing iterative detection to determine a first priori log-likelihood ratio, and performing an external iteration of decoding and decoding verification according to a real-time confidence order corresponding to the first priori log-likelihood ratio, so as to determine a first posteriori log-likelihood ratio of each user and update as a successfully decoded user or an unsuccessfully decoded user, and update an external iteration count;
determining whether there is an unsuccessfully decoded user and whether the external iteration count reaches an external iteration threshold;
if there is an unsuccessfully decoded user and the external iteration count does not reach the external iteration threshold, successively performing an external iteration for each unsuccessfully decoded user using the received signal and each first posteriori log-likelihood ratio, so as to determine a second posteriori log-likelihood ratio of each unsuccessfully decoded user, update as the successfully decoded user or the unsuccessfully decoded user, and update the external iteration count; and
when it is determined that there is no unsuccessfully decoded user or that the external iteration count reaches the external iteration threshold, outputting a decoded bit sequence consisting of decoded bits of each user.

In some embodiments, the step of “in response to receiving a received signal superimposed by transmissions from a plurality of users, successively performing, based on the received signal and an initialized posteriori log-likelihood ratio of each user, message passing iterative detection to determine a first priori log-likelihood ratio, and performing an external iteration of decoding and decoding verification according to a real-time confidence order corresponding to the first priori log-likelihood ratio, so as to determine a first posteriori log-likelihood ratio of each user and update as a successfully decoded user or an unsuccessfully decoded user, and update an external iteration count” comprises:
in response to receiving the received signal superimposed by transmissions from the plurality of users, determining the initialized posteriori log-likelihood ratio for each user;
performing the message passing iterative detection using the received signal and each initialized posteriori log-likelihood ratio, and outputting the first priori log-likelihood ratio for each user;
calculating the real-time confidence level based on each first priori log-likelihood ratio, and sorting to determine the real-time confidence order;
selecting, according to the real-time confidence order, a user with a highest confidence level as a to-be-decoded user;
performing decoding based on a first priori log-likelihood ratio of the to-be-decoded user, and determining a corresponding first posteriori log-likelihood ratio;
performing decoding verification using the first posteriori log-likelihood ratio, and determining the to-be-decoded user as the successfully decoded user or the unsuccessfully decoded user according to a determination of whether decoding is successful;
performing message passing iterative detection for all users using each initialized posteriori log-likelihood ratio that has been updated correspondingly with a current first posteriori log-likelihood ratio, and determining a new real-time confidence order for undecoded users; and
selecting, according to the new real-time confidence order, a user with a highest confidence level as a new to-be-decoded user for decoding, until the first posteriori log-likelihood ratio for each user is determined, each user is updated as a successfully decoded user or an unsuccessfully decoded user, and the external iteration count is updated.

In some embodiments, the step of “performing the message passing iterative detection using each initialized posteriori log-likelihood ratio, and outputting the first priori log-likelihood ratio for each user” comprises:
performing message iterative transmission based on each initialized posteriori log-likelihood ratio, and determining a priori log-likelihood ratio for any user in any current transmission round;
if the current transmission round is 1, calculating an average absolute change using the initialized posteriori log-likelihood ratio of any user and the priori log-likelihood ratio at the current transmission round;
if the current transmission round is greater than 1, calculating an average absolute change using the priori log-likelihood ratio of any user at a previous transmission round and the priori log-likelihood ratio at the current transmission round; and
when the average absolute change is less than a change threshold or the current transmission round reaches a transmission round threshold, outputting the priori log-likelihood ratio at the current transmission round as the first priori log-likelihood ratio of any user.

In some embodiments, the step of “performing decoding verification using the first posteriori log-likelihood ratio, and determining the to-be-decoded user as the successfully decoded user or the unsuccessfully decoded user according to a determination of whether decoding is successful” comprises:
performing the decoding verification using a hard decision result of the first posteriori log-likelihood ratio of the to-be-decoded user;
if the decoding verification is passed, determining the to-be-decoded user as the successfully decoded user, and using a corresponding hard decision result as a decoded bit; and
if there is a hard decision result that does not pass the decoding verification, determining the to-be-decoded user as the unsuccessfully decoded user.

In some embodiments, the real-time confidence level is an average mutual information based on the priori log-likelihood ratio.

In a second aspect, this application provides a R-SDD receiver based on SCMA, comprising:
an SCMA detector;
a channel decoder; and
a decoding order controller;
wherein the SCMA detector is configured to perform, based on a received signal superimposed by transmissions from a plurality of users and an initialized posteriori log-likelihood ratio of each user or a first posteriori log-likelihood ratio of each user, message passing iterative detection for each user or for each unsuccessfully decoded user, and correspondingly determine a first priori log-likelihood ratio for each user or a second priori log-likelihood ratio for each unsuccessfully decoded user;
the channel decoder is configured to perform decoding and decoding verification based on each first priori log-likelihood ratio or each second priori log-likelihood ratio; determine the first posteriori log-likelihood ratio for each user or the second posteriori log-likelihood ratio for each unsuccessfully decoded user; update and determine a successfully decoded user or an unsuccessfully decoded user, update an external iteration count according to the first posteriori log-likelihood ratio or the second posteriori log-likelihood ratio; and determine whether there is an unsuccessfully decoded user and whether the external iteration count reaches an external iteration threshold; and when it is determined that there is no unsuccessfully decoded user or that the external iteration count reaches the external iteration threshold, output a decoded bit sequence consisting of decoded bits of each user; and
the decoding order controller is configured to determine a real-time confidence order using a real-time confidence level corresponding to each first priori log-likelihood ratio; or, if there is an unsuccessfully decoded user and the external iteration count does not reach the external iteration threshold, determine a real-time confidence order using a real-time confidence level corresponding to each second priori log-likelihood ratio of each unsuccessfully decoded user; and control, according to the real-time confidence order, the SCMA detector and the channel decoder to successively perform external iterations of message passing iterative detection, decoding, and decoding verification.

In a third aspect, this application provides a SCMA system, comprising:
a transmitter; and
the above-mentioned R-SDD receiver;
wherein the transmitter is configured to encode, map, superimpose, and transmit information bit sequences of the plurality of users to the R-SDD receiver; and
the R-SDD receiver is configured to receive the received signal transmitted by the transmitter and decode to output the decoded bit sequence.

In a fourth aspect, this application provides a computer device, comprising:
a memory; and
a processor;
wherein the memory is configured to store a computer program; and the computer program is executed by the processor to perform the above-mentioned R-SDD method.

In a fifth aspect, this application provides a computer-readable storage medium, wherein the computer-readable storage medium is configured to store a computer program/instructions; and the computer program/instructions are executed by a processor to implement the above-mentioned R-SDD method.

In a sixth aspect, this application provides a computer program product, comprising:
a computer program/instructions;
wherein the computer program/instructions are executed by a processor to implement the above-mentioned R-SDD method.

Compared to the prior art, the present disclosure has the following beneficial effects.

This application provides the R-SDD method based on SCMA. The method includes the following steps.

In response to receiving the received signal superimposed by transmissions from a plurality of users, message passing iterative detection is successively performed based on the received signal and the initialized posteriori log-likelihood ratio of each user to determine the first priori log-likelihood ratio. The external iteration of decoding and decoding verification is performed according to the real-time confidence order corresponding to the first priori log-likelihood ratio, so as to determine the first posteriori log-likelihood ratio of each user, update each user as a successfully decoded user or an unsuccessfully decoded user, and update the external iteration count.

A determination is made as to whether there is an unsuccessfully decoded user and whether the external iteration count reaches the external iteration threshold.

If there is an unsuccessfully decoded user and the external iteration count does not reach the external iteration threshold, the external iteration for each unsuccessfully decoded user is successively performed using the received signal and each first posteriori log-likelihood ratio, so as to determine the second posteriori log-likelihood ratio of each unsuccessfully decoded user, update each unsuccessfully decoded user as a successfully decoded user or an unsuccessfully decoded user, and update the external iteration count.

When it is determined that there is no unsuccessfully decoded user or that the external iteration count reaches the external iteration threshold, the decoded bit sequence consisting of decoded bits of each user is output.

Based on the above solution, the successive decoding structure that performs external iterations successively is adopted. Simultaneously, the decoding timing of users is dynamically reordered by the confidence order in each external iteration round, so that users decoded later benefit from the latest soft information output of previously decoded users. Furthermore, since unsuccessfully decoded users are dynamically determined in each external iteration round to proceed to the next external iteration round, this not only saves computational resources but also allows the number of decoding iterations to be set to any integer according to hardware conditions. Overall, this achieves a more flexible trade-off between performance and complexity, helping to improve the receiver performance of SCMA systems within a limited complexity.

### BRIEF DESCRIPTION OF THE DRAWINGS

In order to illustrate the technical solutions in the embodiments of the present disclosure or in the prior art more clearly, the drawings needed in the description of embodiments or the prior art will be briefly introduced below. Obviously, for those of ordinary skill in the art, other drawings can be obtained based on these drawings without exerting creative efforts.

FIG. 1 is a flowchart illustrating a R-SDD method according to Embodiment 1 of the present disclosure;

FIG. 2 is a block diagram of a SCMA system with an IDD receiver according to Embodiment 1 of the present disclosure;

FIG. 3 illustrates a decoding sequence example for an IDD receiver and an R-SDD receiver according to Embodiment 1 of the present disclosure;

FIGS. 4a and 4b are complexity comparison diagrams of a single codeword between the R-SDD receiver and the IDD receiver according to Embodiment 1 of the present disclosure, where FIG. 4a: complexity of addition operation, and FIG. 4b: complexity of tanh operation;

FIG. 5 is a first bit error rate (BER) curve comparison diagram between the R-SDD receiver and the IDD receiver according to Embodiment 1 of the present disclosure;

FIG. 6 is a second BER curve comparison diagram between the R-SDD receiver and the IDD receiver according to Embodiment 1 of the present disclosure;

FIG. 7 is a schematic structural diagram of a R-SDD receiver based on SCMA according to Embodiment 2 of the present disclosure; and

FIG. 8 is a schematic structural diagram of a SCMA system according to Embodiment 3 of the present disclosure.

### DETAILED DESCRIPTION OF EMBODIMENTS

The embodiments of the present disclosure provide a R-SDD method and a R-SDD receiver based on SCMA to improve the receiver performance of SCMA systems within the existing limited complexity.

In order to make the purpose, technical features, and advantages of the present disclosure clearer, the technical solutions in the embodiments of the present disclosure will be clearly and completely described below with reference to the accompanying drawings. Obviously, provided herein are merely some embodiments of the disclosure. For those of ordinary skill in the art, other embodiments obtained based on these embodiments of the present disclosure without creative efforts fall within the scope of protection of the present disclosure. Terms such as “first” and “second” are used to distinguish similar objects and do not necessarily describe a specific sequence or order.

### Embodiment 1

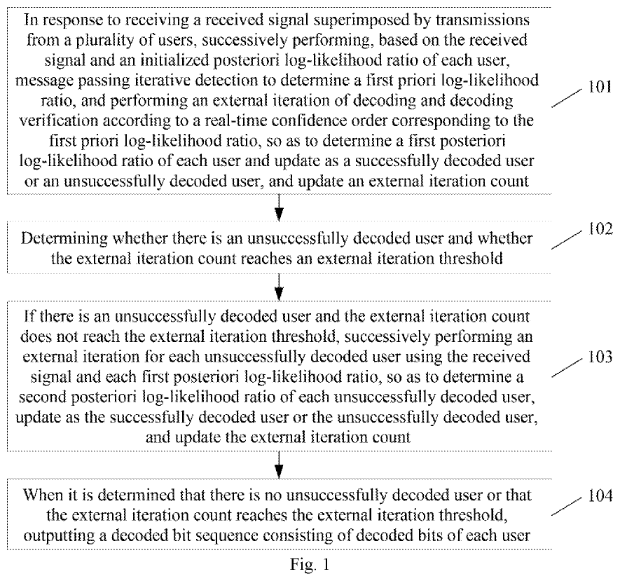

FIG. 1 illustrates a R-SDD method based on SCMA provided in Embodiment 1 of the present disclosure. It should be noted that this embodiment is applied to a SCMA system, which typically includes a transmitting end and a receiving end. At the transmitting end, a channel coding scheme preferably employs a Protograph Low-Density Parity-Check (P-LDPC) code. The information bit sequence

$${b}_{j} = {[ {b}_{j}^{1} , {b}_{j}^{2} , … , {b}_{j}^{l} ]}^{T}$$

of each user j (j=1, 2, . . . , J) is encoded by a channel encoder into a codeword

$${c}_{j} = {[ {c}_{j}^{1} , {c}_{j}^{2} , … , {c}_{j}^{n} ]}^{T} ,$$

where j is the user index j, J is the total number of users, l represents the information bit length,

$${b}_{j}^{l}$$

denotes the l-th information bit of the user j, [·]^{T} indicates the transpose operation, n is the codeword length, and

$${c}_{j}^{n}$$

denotes the n-th encoded bit of the user j. Subsequently, every M=log₂M encoded bits

$${[ {c}_{j}^{1} , {c}_{j}^{2} , … , {c}_{j}^{M} ]}^{T}$$

are grouped into one set, where M is the modulation order. According to a constellation diagram Xⱼ of size M, the set of encoded bits are mapped by an SCMA encoder into a K-dimensional modulation symbol sequence

$${x}_{j} = {[ {x}_{j}^{1} , {x}_{j}^{2} , … {x}_{j}^{K} ]}^{T} ,$$

where each dimension of xⱼ corresponds to a specific resource. Due to the sparsity of the SCMA system, most dimensions of xⱼ are zero. Finally, the modulation symbol sequences of all users are summed and transmitted to the receiving end through the channel. The receiving signal captured by the receiver is denoted as

$$y = {\sum }_{j = 1}^{J} diag ( {h}_{j} ) {x}_{j} + n ,$$

where y=[y₁, y₂, . . . , y_{K}]^{T} represents the received signal, hⱼ=[h₁ⱼ, h₂ⱼ, . . . , h_{Kj}]^{T} denotes the channel fading vector of the user j, and n=[n₁, n₂, . . . , n_{K}]^{T} represents the channel noise. After receiving y, the receiving end recovers the information bits according to the method described below in this embodiment. In specific implementation, the method includes the following steps.
Step 101: When a received signal superimposed by transmissions from a plurality of users is received, based on the received signal and an initialized posteriori log-likelihood ratio of each user, message passing iterative detection is successively performed to determine a first priori log-likelihood ratio, and an external iteration of decoding and decoding verification is conducted according to a real-time confidence order corresponding to the first priori log-likelihood ratio, so as to determine a first posteriori log-likelihood ratio of each user and update as a successfully decoded user or an unsuccessfully decoded user, and update an external iteration count.

The received signal refers to the corresponding signal captured at the receiving end after a user transmits a signal at the transmitting end.

The log-likelihood ratios refer to a logarithmic metric used to measure the relative likelihood of a bit being 0 or 1, and it is a type of soft information. The posteriori log-likelihood ratio refers to the log-likelihood ratio output through decoding iterations. The priori log-likelihood ratio refers to the log-likelihood ratio output through message passing iterative detection. It should be understood that the priori log-likelihood ratios and the posteriori log-likelihood ratios obtained from any external iteration round among different external iteration rounds may be distinguished using terms such as “first,” “second,” etc.

The initialized posterior log-likelihood ratio refers to the initialized preset posterior log-likelihood ratio assigned because, in the first external iteration round, message passing iterative detection is performed before decoding, and during the message passing iterative detection process, no corresponding posteriori log-likelihood ratio is obtained from decoding.

The real-time confidence level refers to a confidence level calculated during the external iteration process. The confidence level is used to evaluate the decoding priority of a user. The real-time confidence order refers to the order formed by sorting a plurality of real-time confidence levels.

The successfully decoded user refers to a user that has completed all decoding. Correspondingly, the unsuccessfully decoded user refers to a user that has not yet completed all decoding.

The external iteration count refers to the cumulative number of times a round of external iteration has been completed. Each external iteration round includes performing, for all users that need to undergo the current external iteration, one round of message passing iterative detection, decoding, and decoding verification.

In an embodiment, step 101 includes the following sub-steps.
S11: Upon receiving the received signal superimposed by transmissions from the plurality of users, the initialized posteriori log-likelihood ratio for each user is determined.
S12: The message passing iterative detection is performed using the received signal and each initialized posteriori log-likelihood ratio, so as to output the first priori log-likelihood ratio for each user.
S13: The real-time confidence levels are calculated based on each first priori log-likelihood ratio and are sorted to determine the real-time confidence order.
S14: According to the real-time confidence order, a user with the highest confidence level is selected as a to-be-decoded user.
S15: Decoding is performed based on a first priori log-likelihood ratio of the to-be-decoded user to determine a corresponding first posteriori log-likelihood ratio.
S16: Decoding verification is performed using the first posteriori log-likelihood ratio, and the to-be-decoded user is determined as the successfully decoded user or the unsuccessfully decoded user according to the determination of whether decoding is successful.
S17: Message passing iterative detection is performed for all users using each initialized posteriori log-likelihood ratio that has been updated correspondingly with the current first posteriori log-likelihood ratio, so as to determine a new real-time confidence order for undecoded users.
S18: According to the new real-time confidence order, a user with the highest confidence level is selected as a new to-be-decoded user for decoding, until the first posteriori log-likelihood ratio for each user is determined, each user is updated as a successfully decoded user or an unsuccessfully decoded user, and the external iteration count is updated.

The to-be-decoded user refers to a user who will undergo decoding in the current round of the external iteration.

The undecoded user refers to a user that has not yet been decoded in the current round of external iteration.

It should be noted that when the received signal transmitted by superposition of a plurality of users is received, this embodiment employs an external iteration scheme to obtain decoding results for each user. For each round of external iteration, a corresponding number of message passing iterative detections, decoding and decoding verifications are set according to the number of users requiring external iteration in the current round.

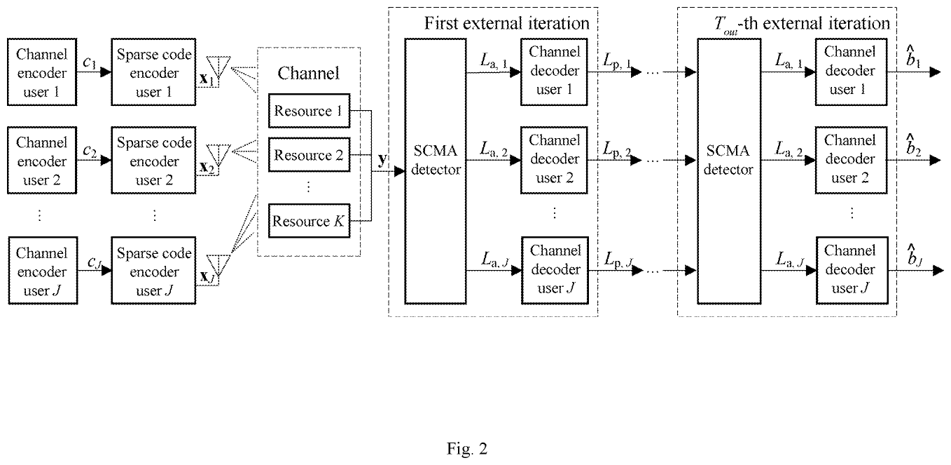

Different from the processing architecture of the traditional IDD receiver shown in FIG. 2, which performs decoding for each user independently and in parallel, this embodiment adopts the successive decoding structure. Within any external iteration round, the message passing iterative detection and decoding operations among users are executed successively, allowing later-decoded users to utilize the updated posteriori log-likelihood ratios obtained from the decoding of previous users for performing message passing iterative detection. For example, after the first user performs decoding to obtain the first posteriori log-likelihood ratio, the posteriori log-likelihood ratio used by the second user for message passing iterative detection is the first posteriori log-likelihood ratio of the first user and the initialized posteriori log-likelihood ratios of users other than the first user. Meanwhile, users with higher confidence levels are processed first, thereby determining the first priori log-likelihood ratio and the first posteriori log-likelihood ratio for each user. Based on the decoding verification results using the first posteriori log-likelihood ratio, the users are classified as the successfully decoded user or the unsuccessfully decoded user, and the external iteration count is updated for recording.

In specific implementation, the message passing iterative detection refers to iterative detection based on the message passing algorithm (MPA), where the inputs are the received signal y and L_{p,j}, and the output is L_{a,j}. Each message passing iterative detection includes Z MPA inner iterations, where Z is the total number of inner iterations. Before starting the MPA inner iterations,

$${g}_{j \to k}^{0} , ( {g}_{j \to k}^{t}$$

is defined as the mutual information transmitted from the j-th user node to the k-th resource node in the t-th message passing inner iteration) is initialized as follows:

$${g}_{j \to k}^{0} = {{\prod }_{i = 1}}^{M} \frac{1}{1 + exp [ {( - 1 )}^{{c}_{j}^{n}} \times {L}_{p , j} ( {c}_{j}^{n} ) ]} .$$

In the above formula, L_{p,j} is the posteriori log-likelihood ratio of the user j,

$${c}_{j}^{n}$$

is the n-th encoded bit of the user j, and L_{p,j}

$$( {c}_{j}^{n} )$$

is the posteriori log-likelihood ratio corresponding to the n-th encoded bit of the user j.

It should be understood that, in the first external iteration round, since message passing iterative detection is performed before decoding, there is no extrinsic information provided by decoding at this time. Therefore, the posteriori log-likelihood ratio L_{p,j} is initialized to 0, and

$${g}_{j \to k}^{0}$$

is initialized as

$${g}_{j \to k}^{0} = \frac{1}{M} .$$

After the initialization is completed, the message passing inner iterations begin. Taking the t-th message passing inner iteration as an example, each MPA inner iteration includes the following three steps.
1) All combinations of K and J are traversed, and the mutual information transmitted from K resource nodes to J user nodes are calculated respectively. The mutual information transmitted from the k-th resource node to the j-th user node can be calculated using the following formula:

$${m}_{k \to j}^{t} ( {x}_{j} ) = {\sum }_{\{ {x}_{i} \vert i ∈ N ( k ) \backslash j \}} exp ( - \frac{1}{{σ}^{2}} {‖ {y}_{k} - {\sum }_{i , {x}_{ki}} {h}_{ki} {x}_{ki} ‖}^{2} ) {\prod }_{i ∈ N ( k ) \backslash j} {g}_{i \to k}^{t - 1} ( {x}_{i} ) .$$

In the above formula, j is the user index j, xⱼ is the modulation symbol sequence of the user j, t is the transmission round index t, i is the user index i, xᵢ is the modulation symbol sequence of the user i, k is the resource node index k, N(k) is the set of users carried by the k-th resource node, N(k)\j is the subset of the set of users carried by the k-th resource node after removing the user j, σ² is the noise variance, yₖ is the received signal of the k-th resource node, hₖᵢ is the channel fading vector from the i-th user to the k-th resource node, xₖᵢ is the modulation symbol of the i-th user on the k-th resource node,

$${g}_{i \to k}^{t - 1}$$

is the mutual information transmitted from the i-th user node to the k-th resource node in the (t−1)-th message passing inner iteration, and

$${m}_{k \to j}^{t}$$

is the mutual information transmitted from the k-th resource node to the j-th user node in the t-th message passing inner iteration.
2) All combinations of K and J are traversed, and the mutual information transmitted from J user nodes to K resource nodes are calculated respectively using the following formula:

$${g}_{j \to k}^{t} ( {x}_{j} ) = \frac{1}{M} {\prod }_{r ∈ R ( j ) \backslash k} {m}_{r \to j}^{t} ( {x}_{j} ) .$$

In the above formula,

$${g}_{j \to k}^{t}$$

is the mutual information transmitted from the j-th user node to the k-th resource node in the t-th message passing inner iteration, M is the constellation size, r is the resource node index r, R(j) is the set of resource nodes used by the user j, R(j)\k is the subset of the set of resource nodes used by the user j excluding the resource node k, and

$${m}_{r \to j}^{t}$$

is the mutual information transmitted from the r-th resource node to the j-th user node during the t-th message passing inner iteration.
3) The posterior probability of each modulation symbol and the priori log-likelihood ratio are calculated using the following formula:

$$Pr ( {x}_{j} ) = \frac{1}{M} {\prod }_{k ∈ R ( j )} {m}_{k \to j}^{t} ( {x}_{j} ) ; and$$

$${L}_{a , j}^{t} = log \frac{{\sum }_{\{ {x}_{j} ∈ X \vert {b}^{l} = 0 \}} Pr ( {x}_{j} )}{{\sum }_{\{ {x}_{j} ∈ X \vert {b}^{l} = 1 \}} Pr ( {x}_{j} )} .$$

In the above formulas, xⱼ is the modulation symbol sequence of the user j, Pr(·) is the posterior probability, M is the constellation size, xⱼ is the modulation symbol of the user j,

$${L}_{a , j}^{t}$$

is the priori log-likelihood ratio of the user j in the t-th message passing inner iteration, b^{l} is the l-th information bit, {xⱼ∈X|b^{l}=0} is the modulation symbol corresponding to the information bit of 0 in the constellation diagram for the user j, and {xⱼ∈X|b^{l}=1} is the modulation symbol corresponding to the information bit of 1 in the constellation diagram for the user j.

After completing Z MPA inner iterations for the user j according to the above three-step process, the result of the last MPA inner iteration is taken as the priori log-likelihood ratio for the user j output after the message passing iterative detection in the current external iteration round, i.e.,

$${L}_{a , j} = {L}_{a , j}^{Z} .$$

In an embodiment, the sub-step S12 includes following steps (S121)-(S124).
S121: Message iterative transmission is performed based on each initialized posteriori log-likelihood ratio, and the priori log-likelihood ratio for any user in any current transmission round is determined.
S122: If the current transmission round is 1, the average absolute change is calculated using the initialized posteriori log-likelihood ratio of any user and the priori log-likelihood ratio at the current transmission round.
S123: If the current transmission round is greater than 1, the average absolute change is calculated using the priori log-likelihood ratio of any user at a previous transmission round and the priori log-likelihood ratio at the current transmission round.
S124: When the average absolute change is less than the change threshold or the current transmission round reaches the transmission round threshold, the priori log-likelihood ratio at the current transmission round is output as the first priori log-likelihood ratio of any user.

It should be noted that, to further reduce complexity, this embodiment also introduces an intelligent early-stop mechanism for message passing iterative detection. Specifically, in each MPA inner iteration, the average absolute change of LLR values between the previous and current iterations (before and later) is calculated. If the average absolute change is below a set change threshold, it indicates that the information has converged, at this point, the MPA iteration is terminated, and the current transmission iteration's

$${L}_{a , j}^{t}$$

is directly used as the output, thereby avoiding subsequent ineffective calculations. The calculation process for the average absolute change V_{avg} includes:

$${V}_{avg} = \{ \begin{matrix}E [ \vert {L}_{a , j}^{t} - {L}_{p , j} \vert ] , t = 1 \\ E [ \vert {L}_{a , j}^{t} - {L}_{a , j}^{t - 1} \vert ] , t > 1\end{matrix} .$$

It should be understood that this mechanism leverages the characteristic that message passing iterative detection has completed most of the effective information exchange within the first few iterations. Through testing, setting the change threshold to 30 can effectively reduce the complexity of the detector without significantly affecting performance.

In practical, this embodiment employs belief propagation (BP) decoding for P-LDPC codes, with L_{a,j} as the input and L_{p,j} as the output. This decoding process also includes Y rounds of BP inner iterations, and the specific calculation process is as follows.
1) The likelihood information L_{αβ} of c_{α}→v_{β} is calculated by the following formula:

$${L}_{α β} = 2 {tanh}^{- 1} [ {\prod }_{λ ∈ V ( α ) \backslash β} tanh ( \frac{1}{2} {L}_{λ α} ) ] .$$

2) The likelihood information L_{βα} of v_{β}→c_{α} is calculated by the following formula:

$${L}_{β α} = {L}_{a , j} + {\prod }_{φ ∈ C ( β ) \backslash α} {L}_{φ β} .$$

3) The posterior likelihood information L_{p,j}, of v_{β} is calculated by the following formula:

$${L}_{p , j} = {L}_{a , j} + {\prod }_{α ∈ C ( β )} {L}_{αβ} .$$

After the BP inner iterations are completed, the final L_{p,j} is output.

In above formulas, α is the check node index α, c_{α} is the α-th check node, β is the variable node index β, v_{β} is the β-th variable node, L_{αβ} is the log-likelihood ratio from the α-th check node to the β-th variable node, λ is the variable node index λ, V(α)\β is the set of variable nodes associated with the α-th check node excluding the β-th variable node, L_{λα} is the log-likelihood ratio from the λ-th variable node to the α-th check node, tan h(·) is the hyperbolic tangent function, L_{βα} is the log-likelihood ratio from the β-th variable node to the α-th check node, φ is the check node index φ, C(β)\α is the set of check nodes associated with the β-th variable node excluding the α-th check node, L_{φβ} is the log-likelihood ratio from the φ-th check node to the β-th variable node, and L_{α,j} is the priori log-likelihood ratio of the user j.

In an embodiment, the sub-step S16 includes following steps (S161)-(S163).
S161, Decoding verification is performed using the hard decision result of the first posteriori log-likelihood ratio of the to-be-decoded user.
S162, If the decoding verification is passed, the user is determined to be the successfully decoded user, and the corresponding hard decision result is used as the decoded bit.
S163, If there are hard decision results that fail to pass the decoding verification, the corresponding user is determined to be the unsuccessfully decoded user.

It should be noted that decoding verification refers to the verification for determining whether decoding has been successfully performed, and this may be configured according to specific encoding conditions. Taking the P-LDPC code as an example, the corresponding decoding verification may employ parity check verification. A (n,l) P-LDPC code includes n−l parity check equations, where n is the codeword length, and l is the information bit length. If the LLR obtained by a user after decoding passes all parity checks (i.e., the hard decision result of the LLR satisfies all parity check equations), the user is considered to have been successfully decoded. The user is accordingly classified as the successfully decoded user or the unsuccessfully decoded user, and the hard decision result of the successfully decoded user is correspondingly determined as the decoded bits.

In an embodiment, the real-time confidence level is the average mutual information (AMI) based on the priori log-likelihood ratio.

It should be noted that in this embodiment, the AMI is used as the evaluation criterion for each user's confidence level, and the calculation formulas are expressed as follows:

$${AMI}_{j} = E [ {f}_{I} ( {L}_{a , j} ) ] ; and {f}_{I} ( θ ) = \frac{1}{1 + {e}^{θ}} {log}_{2} \frac{2}{1 + {e}^{θ}} + \frac{1}{1 + {e}^{- θ}} {log}_{2} \frac{2}{1 + {e}^{- θ}} .$$

In above formulas, AMIⱼ represents AMI for the j-th user, E[·] represents the mathematical expectation function, and f₁(θ) is the function that converts the log-likelihood ratio to mutual information.
Step 102: It is determined whether there is an unsuccessfully decoded user and whether the external iteration count reaches the external iteration threshold.

It should be noted that, for each external iteration round, the set external iteration termination condition is that all users have been successfully decoded (i.e., satisfying the check constraints), or the set external iteration threshold (such as the maximum number of external iterations, typically 5 to 10 times) has been reached.
Step 103: If there is an unsuccessfully decoded user and the external iteration count does not reach the external iteration threshold, the external iteration is successively performed for each unsuccessfully decoded user using the received signal and each first posteriori log-likelihood ratio, so as to determine the second posteriori log-likelihood ratio of each unsuccessfully decoded user, update each unsuccessfully decoded user as the successfully decoded user or the unsuccessfully decoded user, and update the external iteration count.

It should be noted that, if there is an unsuccessfully decoded user and the external iteration count does not reach the external iteration threshold, it indicates that external iteration needs to continue. At this time, successfully decoded users will no longer participate in subsequent external iterations to save computational resources. Therefore, confidence levels are evaluated for each unsuccessfully decoded user to determine a new real-time confidence order for decoding. In specific implementation, successive decoding and dynamic decoding order reordering are performed according to a process similar to step 101, including the following sub-steps.
S21: Message passing iterative detection is performed for unsuccessfully decoded users according to the received signal and each first posteriori log-likelihood ratio, so as to output the second priori log-likelihood ratio for each unsuccessfully decoded user.
S22: The real-time confidence order is determined by sorting using the real-time confidence level associated with each second priori log-likelihood ratio.
S23: According to the real-time confidence order, a user with the highest confidence level is selected as the to-be-decoded user.
S24: Decoding is performed based on the second priori log-likelihood ratio of the to-be-decoded user, and the corresponding second posteriori log-likelihood ratio is generated.
S25: Decoding verification is performed using the second posteriori log-likelihood ratio, and the to-be-decoded user is determined as a new successfully decoded user or a new unsuccessfully decoded user according to a result of whether decoding is successful.
S26: Message passing iterative detection is performed for undecoded users using each first posteriori log-likelihood ratio that has been updated correspondingly with the current second posteriori log-likelihood ratio, and a new real-time confidence order is determined.
S27: According to the real-time confidence order, a user with the highest confidence level is selected as a new to-be-decoded user for decoding, until the second posteriori log-likelihood ratio for each unsuccessfully decoded user from the previous external iteration round is determined, each such user is updated as the successfully decoded user or the unsuccessfully decoded user, and the external iteration count is updated.
Step 104: When it is determined that there is no unsuccessfully decoded user or that the external iteration count reaches the external iteration threshold, the decoded bit sequence consisting of decoded bits of each user is output.

It should be noted that if the external iteration termination condition is met, the decoded bit sequence b consisting of the decoded bits of each user is output as the decoding result. If the external iteration termination condition is not met, a process similar to step 103 is performed, in which the received signal and the second posteriori log-likelihood ratio of each unsuccessfully decoded user are used to calculate the real-time confidence level for each unsuccessfully decoded user, the real-time confidence levels are sorted to determine the real-time confidence order, and external iterations are continued according to the real-time confidence order until it is determined that there is no unsuccessfully decoded user or that the external iteration count reaches the external iteration threshold, at which time the decoding result is output.

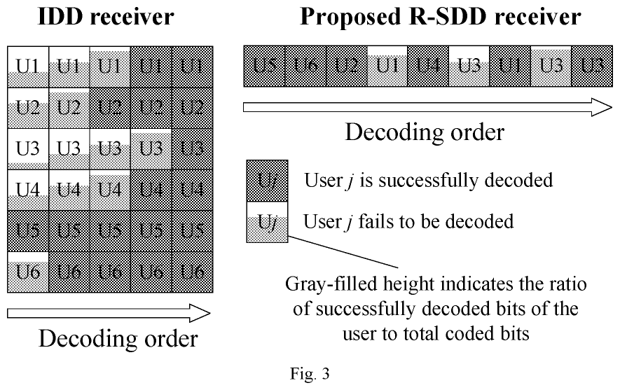

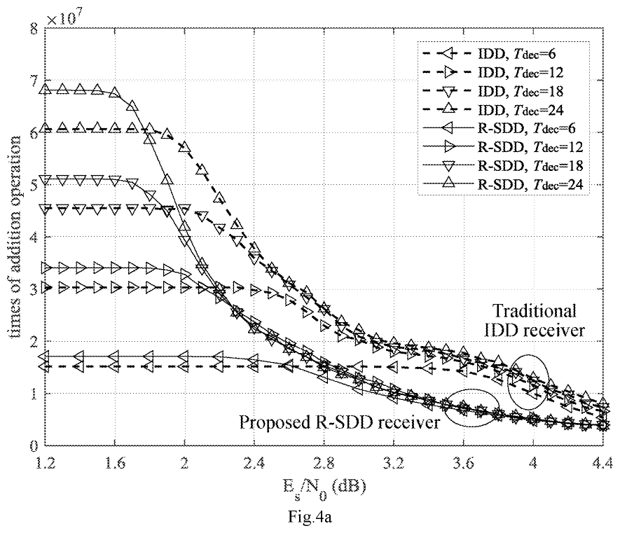

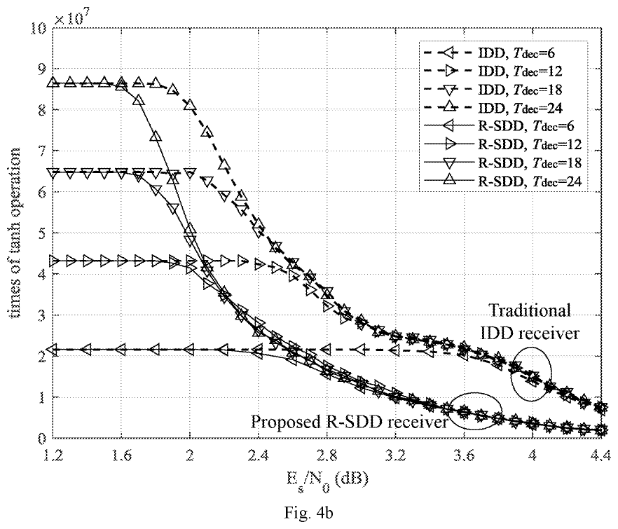

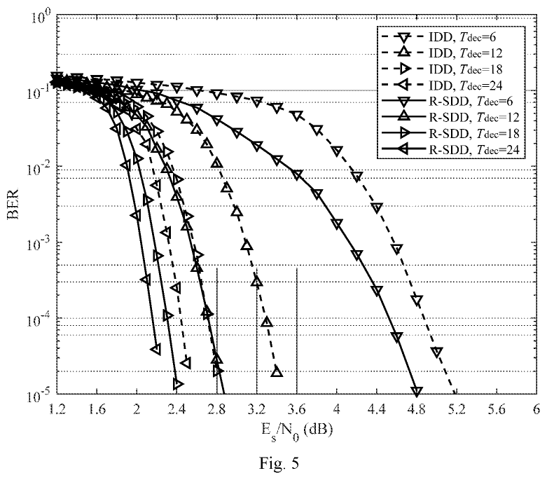

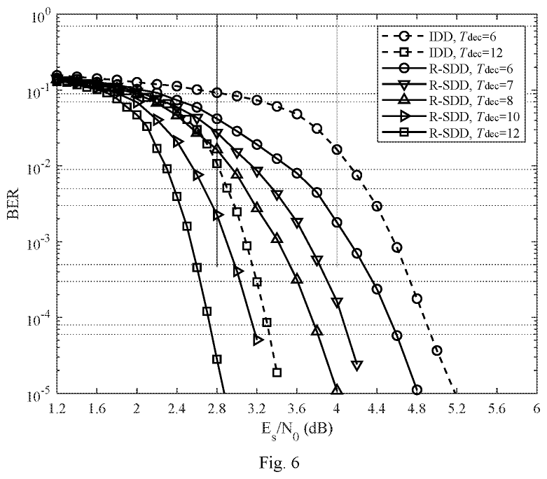

To better illustrate the technical effects of this embodiment, with reference to FIGS. 3 to 6, the solution of this embodiment is applied to a receiver and compared with a traditional IDD receiver.
1) To more intuitively demonstrate the dynamic reordering mechanism of the decoding order, FIG. 3 compares the decoding order of the traditional IDD receiver and the proposed R-SDD receiver in this disclosure. In this example, User 3 has the lowest confidence level and is the performance bottleneck of the entire system, while User 5 and User 6 have the highest confidence levels. In the traditional IDD receiver, the decoding for each user is executed independently and in parallel. In contrast, the R-SDD receiver always places User 3 at the end of the decoding order, allowing User 3 to fully benefit from extrinsic information provided by other users, thereby accelerating system convergence.
2) FIGS. 4a and 4b compare the computational complexity of a single codeword between the proposed R-SDD receiver in this embodiment and the traditional IDD receiver. The channel coding scheme uniformly uses (3, 6) regular protograph codes with a code length of 2400. FIG. 4a shows the complexity of addition operations, and FIG. 4b shows the complexity of tanh operations. For ensure a fair comparison, both receivers are equipped with an intelligent early stopping mechanism, where T_{dec} represents the maximum number of decoders allowed by the system. It can be seen that, compared with the traditional IDD receiver, the proposed R-SDD receiver has lower computational complexity.
3) To verify the effectiveness of the proposed R-SDD receiver, BER performance simulations are performed in an SCMA system with 6 users and 4 resources. All receivers uniformly use an MU-2 protograph code with a code rate of 1/2 and a code length of 2400, the BP algorithm is used for decoding with the maximum number of BP iterations of 100, and simulations are performed based on an AWGN channel. The BER simulation results are shown in FIGS. 5 and 6. FIG. 5 compares the performance of the proposed R-SDD receiver and the traditional IDD receiver under the same T_{dec}. It can be observed that the R-SDD receiver delivers considerable performance gains. It should be noted that this performance gain is not achieved at the cost of increased complexity. In FIG. 6, different T_{dec} are set. The number of decoders in the traditional IDD receiver must be set to an integer multiple of the number of users, while in the R-SDD receiver, the arbitrariness in specifying the number of decoders is more prominent, demonstrating the flexibility of the R-SDD receiver.

In summary, compared to traditional IDD receivers, the R-SDD receiver offers superior performance, lower computational complexity, and more flexible hardware deployment.

In the embodiments, the successive decoding structure that performs external iterations successively is adopted. Simultaneously, the decoding timing of users is dynamically adjusted by the confidence order in each external iteration round, the user with the current “lowest confidence level” is arranged to be processed last, so that it benefits from the latest soft information outputs of other users. Furthermore, since unsuccessfully decoded users are dynamically determined in each external iteration round to proceed to the next external iteration round, this not only saves computational resources but also allows the number of decoding iterations to be set to any integer according to hardware conditions. Overall, higher mutual information propagation efficiency results in lower bit error rate and lower computational complexity, achieving a more flexible trade-off between performance and complexity.

### Embodiment 2

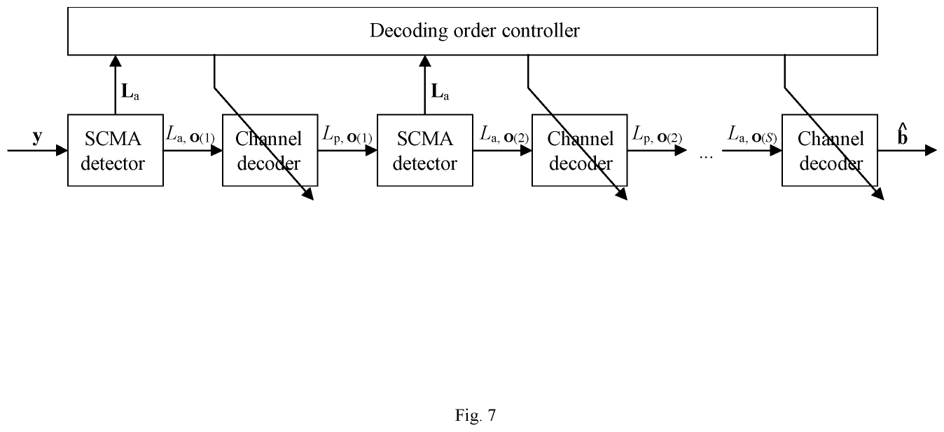

Referring to FIG. 7, a R-SDD receiver based on SCMA provided includes a SCMA detector, a channel decoder, and a decoding order controller.

The SCMA detector is configured to perform, based on the received signal superimposed by transmissions from a plurality of users as well as the initialized posteriori log-likelihood ratio of each user or the first posteriori log-likelihood ratio of each user, message passing iterative detection for each user or for each unsuccessfully decoded user; and correspondingly determine the first priori log-likelihood ratio for each user or the second priori log-likelihood ratio for each unsuccessfully decoded user.

The channel decoder is configured to perform decoding and decoding verification based on each first priori log-likelihood ratio or each second priori log-likelihood ratio; determine the first posteriori log-likelihood ratio for each user or the second posteriori log-likelihood ratio for each unsuccessfully decoded user; update and determine a successfully decoded user or an unsuccessfully decoded user, update an external iteration count according to the first posteriori log-likelihood ratio or the second posteriori log-likelihood ratio; and determine whether there is an unsuccessfully decoded user and whether the external iteration count reaches the external iteration threshold. When it is determined that there is no unsuccessfully decoded user or that the external iteration count reaches the external iteration threshold, the channel decoder outputs the decoded bit sequence consisting of decoded bits of each user.

The decoding order controller is configured to determine the real-time confidence order using the real-time confidence level corresponding to each first priori log-likelihood ratio. Or, if there is an unsuccessfully decoded user and the external iteration count does not reach the external iteration threshold, the decoding order controller is configured to determine the real-time confidence order using the real-time confidence level corresponding to each second priori log-likelihood ratio of each unsuccessfully decoded user. The decoding order controller is further configured to control, according to the real-time confidence order, the SCMA detector and the channel decoder to successively perform external iterations of message passing iterative detection, decoding, and decoding verification.

It should be noted that in this embodiment, under the control of the decoding order controller based on the confidence order of the corresponding processes, message passing iterative detection is performed via the SCMA detector. The SCMA detector may be the MPA-based SCMA detector. Decoding, decoding verification, determining when to terminate the external iteration, and outputting decoded bits are performed by the channel decoder. The channel decoder may be the BP decoder.

Each external iteration round consists of q SCMA detectors and q channel decoders, where q represents the number of users that currently have not yet been successfully decoded. In the initial first external iteration round, q=J, where J is the total number of users, while in subsequent external iteration rounds, q≤J.

Within one external iteration of each external iteration round, the channel decoders of the users are serially connected through the SCMA detectors, allowing later-decoded users to utilize the mutual information from preceding users. Consequently, the R-SDD receiver possesses a successive decoding structure.

In each external iteration, the R-SDD receiver uses the decoding order controller to prioritize users with higher confidence levels, thereby achieving successive decoding and dynamic decoding order rearrangement. Benefiting from the above design, the R-SDD receiver enables all users to fully utilize the extrinsic information provided by already decoded users, thereby accelerating convergence. Simultaneously, the external iteration can be stopped as soon as the slowest-converging user is successfully decoded, effectively reducing complexity.

In a specific implementation of this embodiment, the SCMA detector is specifically configured to: when receiving the received signal transmitted by superposition of a plurality of users, determine the initialized posteriori log-likelihood ratio for each user; perform message passing iterative detection using the received signal and each initialized posteriori log-likelihood ratio, and output the first priori log-likelihood ratio for each user. The SCMA detector is further configured to perform message passing iterative detection on undecoded users using each initialized posterior log-likelihood ratios that are correspondingly updated with the current first posterior log-likelihood ratio, so as to determine the first priori log-likelihood ratio for each undecoded user.

The channel decoder is specifically configured to: perform decoding based on the first priori log-likelihood ratio of the to-be-decoded user, and determine the corresponding first posteriori log-likelihood ratio; perform decoding verification using the first posteriori log-likelihood ratio, and determine the to-be-decoded user as a successfully decoded user or an unsuccessfully decoded user according to a result of whether decoding is successful; until the first posteriori log-likelihood ratio for each user is determined, and each user is updated as a successfully decoded user or an unsuccessfully decoded user, the external iteration count is updated.

The decoding order controller is specifically configured to: calculate the real-time confidence levels based on each first priori log-likelihood ratio, and sort to determine the real-time confidence order; and select, according to the real-time confidence order, a user with the highest confidence level as the to-be-decoded user.

In a more specific embodiment, message passing iterative detection is performed using the received signal and each initialized posterior log-likelihood ratios to output the first posterior log-likelihood ratio of each user, including the following steps.

Message iterative transmission is performed based on each initialized posteriori log-likelihood ratio, and the priori log-likelihood ratio for any user in any current transmission round is determined.

If the current transmission round is 1, the average absolute change is calculated using the initialized posteriori log-likelihood ratio of any user and the priori log-likelihood ratio at the current transmission round.

If the current transmission round is greater than 1, the average absolute change is calculated using the priori log-likelihood ratio of any user at the previous transmission round and the priori log-likelihood ratio at the current transmission round.

When the average absolute change is less than the change threshold or the current transmission round reaches the transmission round threshold, the priori log-likelihood ratio at the current transmission round is output as the first priori log-likelihood ratio of the to-be-decoded user.

It should be noted that the R-SDD receiver also introduces the intelligent early-stop mechanism for the MPA detector, which determines whether the information has approached convergence by evaluating the average absolute change of the log-likelihood ratios. This mechanism leverages the characteristic that the MPA detector completes most of the effective information exchange within the first few iterations, thereby avoiding subsequent redundant computations.

In a specific implementation of this embodiment, the channel decoder is specifically configured to: perform decoding verification using the hard decision result of the first posteriori log-likelihood ratio of the to-be-decoded user. If the decoding verification is passed, the user is determined to be a successfully decoded user, and the corresponding hard decision result is used as decoded bits. If there is a hard decision result that fails the decoding verification, the corresponding user is determined to be an unsuccessfully decoded user.

In a specific implementation of this embodiment, the real-time confidence level is AMI based on the priori log-likelihood ratio.

In a specific implementation of this embodiment, the SCMA detector is specifically configured to: perform, based on the received signal and each first posteriori log-likelihood ratio, message passing iterative detection for unsuccessfully decoded users, and output the second priori log-likelihood ratio for each unsuccessfully decoded user; and perform message passing iterative detection for undecoded users using each first posteriori log-likelihood ratio that has been correspondingly updated with the current second posteriori log-likelihood ratio, so as to determine the second priori log-likelihood ratio for each undecoded user. Until the second posteriori log-likelihood ratio for each unsuccessfully decoded user from the previous external iteration round is determined, and each user is updated as a successfully decoded user or an unsuccessfully decoded user, the external iteration count is updated.

The channel decoder is specifically configured to: perform decoding based on the second priori log-likelihood ratio of the to-be-decoded user, and generate the corresponding second posteriori log-likelihood ratio; perform decoding verification using the second posteriori log-likelihood ratio, and determine the to-be-decoded user as a new successfully decoded user or a new unsuccessfully decoded user according to a result of whether decoding is successful.

The decoding order controller is specifically configured to: determine the real-time confidence order by sorting the real-time confidence levels associated with each second priori log-likelihood ratio; and select, according to the real-time confidence order, the user with the highest confidence level as the to-be-decoded user.

Regarding the hardware implementation of the receiver, the proposed receiver is primarily embodied as a detection and decoding architecture and a signal processing method. The SCMA detector, the channel decoder, and the decoding order controller in the disclosure can be understood as functional modules in the receiver, representing hardware implementation. These modules can execute corresponding algorithm flows through hardware circuits such as Field-Programmable Gate Array (FPGA), Application-Specific Integrated Circuit (ASIC), and Digital Signal Processor (DSP), thereby completing the detection and decoding process.

The channel decoder serves only as one of the component modules of the R-SDD receiver, and employs the channel decoding algorithms in the prior art. Furthermore, in the proposed R-SDD receiver, the present disclosure does not necessarily limit the decoding algorithm. The innovation of the present disclosure is primarily embodied in the cooperative working architecture among the SCMA detector, the channel decoder, and the decoding order controller (as shown in FIG. 7).

In a specific embodiment, the channel coding employs the P-LDPC code, and accordingly, the channel decoder can be implemented using the BP-based decoding algorithm. In addition, the SCMA detector is an improved structure proposed by the present disclosure, which introduces the early stopping mechanism based on the traditional MPA detector.

The R-SDD receiver proposed in the present disclosure improves information utilization efficiency and interference elimination capability through the following three aspects: introducing the successive decoding structure, dynamic decoding order reordering, and the detector early stopping mechanism.

### (1) Successive Decoding Structure Improves Information Transfer Efficiency

The parallel decoding structure of users in the traditional IDD receiver is changed to the successive detection and decoding structure in the present disclosure, allowing users to sequentially complete detection and decoding in the same external iteration round. Soft information of the decoded user can be immediately fed back to the detector and participate in the detection process of subsequent users, thereby enabling more sufficient information sharing among users within the same iteration round. In contrast, limited by the parallel structure, the traditional IDD receiver cannot exchange soft information among users in the same external iteration round, resulting in low iteration efficiency. Since the main performance bottleneck of the SCMA system arises from multi-user non-orthogonal interference, the successive decoding structure can gradually utilize reliable priori information provided by decoded users during the detection process to more effectively suppress interference for the remaining users, making the log-likelihood ratios output by the detector more reliable, thereby improving the overall convergence speed and BER performance of the system.

### (2) Dynamic Decoding Order Reordering Enables Adaptive Allocation of Computational Resources and Improves Bottleneck User Performance

Based on the successive decoding structure, the present disclosure further introduces the dynamic decoding order reordering mechanism, which adjusts the detection and decoding order according to the current decoding status of users in each external iteration round, so that users with higher confidence levels are prioritized for detection and decoding, while users with the lowest confidence levels and the most difficult convergence are scheduled to be processed last. This strategy allows the system to first obtain decoding results of highly reliable users and use timely their soft information for the detection of subsequent users, thereby gradually reducing the multi-user interference level in the system. For users with performance bottlenecks, since their decoding process occurs after other users have provided sufficient extrinsic information, they can complete decoding under conditions of minimum interference and most sufficient priori information, thereby obtaining the maximum iteration gain and improving the overall BER performance of the system. Furthermore, when some users have been successfully decoded, they can be removed from subsequent iteration processes to avoid redundant computation.

The sources of performance gain can be summarized as follows: 1. high-reliable users converge first; 2. the soft information immediately participates in interference elimination; 3. bottleneck users decode under minimum interference conditions.

### (3) Early Stopping Mechanism Reduces Computational Complexity

To reduce detection complexity, the early stopping mechanism is introduced in the MPA-based detector in the present disclosure, which determines whether the algorithm has converged by monitoring the amount of change in log-likelihood ratios between adjacent iterations. When the change falls below a threshold, the iteration is terminated early, thereby reducing invalid computation and lowering the complexity of the system without significantly affecting detection performance.

In the embodiments, the successive decoding structure that performs external iterations successively is adopted. Simultaneously, the decoding timing of users is dynamically adjusted by the confidence order in each external iteration round, the user with the current “lowest confidence level” is arranged to be processed last, so that it benefits from the latest soft information outputs of other users. Furthermore, since unsuccessfully decoded users are dynamically determined in each external iteration round to proceed to the next external iteration round, this not only saves computational resources but also allows the number of decoding iterations to be set to any integer according to hardware conditions. Overall, higher mutual information propagation efficiency results in lower bit error rate and lower computational complexity, achieving a more flexible trade-off between performance and complexity.

### Embodiment 3

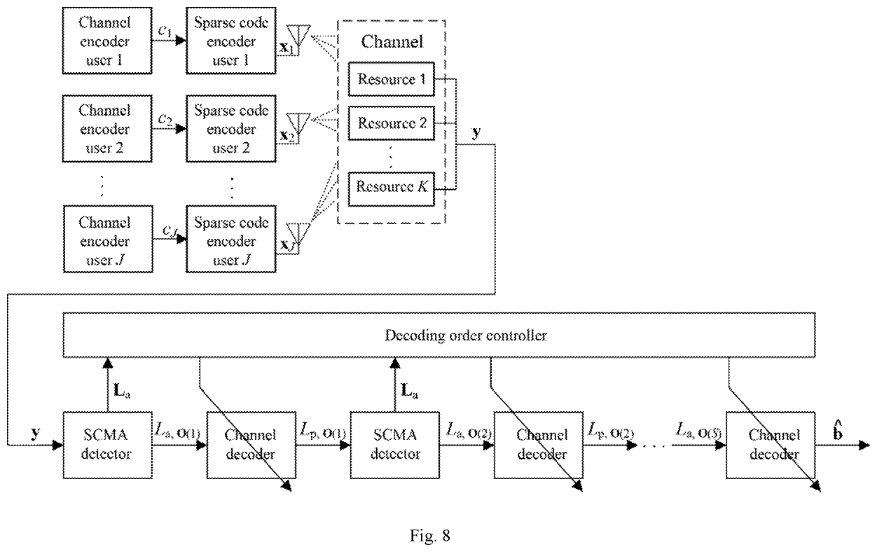

Referring to FIG. 8, a SCMA system provided includes a transmitter and the R-SDD receiver described in Embodiment 2.

The transmitter is configured to encode, map, superimpose, and transmit information bit sequences of a plurality of users to the R-SDD receiver.

The R-SDD receiver is configured to receive the received signal transmitted by the transmitter and decode to output the decoded bit sequence.

It should be noted that the transmitter includes a channel encoder and an SCMA encoder, and the specific processing principles can be found in the prior art. Benefiting from the design of the R-SDD receiver, the R-SDD receiver enables all users to fully utilize the extrinsic information provided by already decoded users, thereby accelerating the overall convergence of the system. Simultaneously, the system can stop the external iterations as soon as the slowest-converging user is successfully decoded, effectively reducing system complexity. Furthermore, this allows the number of decoding iterations to be set to any integer according to hardware conditions, achieving optimization of flexibility and efficiency.

### Embodiment 4

A computer device provided herein includes a memory and a processor. The memory stores a computer program. When the computer program is executed by the processor, it enables the processor to perform the steps of the R-SDD method based on SCMA as described in any of the above embodiments.

### Embodiment 5

A computer-readable storage medium provided herein is configured to store computer program/instructions thereon. When executed by a processor, the computer program/instructions implement the steps of the R-SDD method based on SCMA as described in any of the above embodiments.

### Embodiment 6

A computer program product provided herein includes computer program/instructions. When executed by a processor, the computer program/instructions implement the steps of the R-SDD method based on SCMA as described in any of the above embodiments.

Those skilled in the art can clearly understand that, for the convenience and brevity of description, the specific operational processes of the system and receiver described above may refer to the corresponding processes in the foregoing method embodiments, and will not be repeated here.

In the several embodiments provided in this disclosure, it should be understood that the disclosed systems, receivers, and methods may be implemented in other ways. For example, the device embodiments described above are merely illustrative. For instance, the division of modules is merely a logical functional division, and other division manners may be used in actual implementation. For example, multiple modules or components may be combined or integrated into another system, or some features may be omitted or not performed. In addition, the couplings, direct couplings, or communication connections shown or discussed may be indirect couplings or communication connections through some interfaces, devices, or modules, and may be electrical, mechanical, or other forms.

The modules described as separate components may or may not be physically separate. The components shown as modules may or may not be physical modules, meaning they may be located in a single place or distributed across multiple network modules. Depending on actual needs, some or all of these modules may be selected to achieve the objectives of this embodiment.

Furthermore, in the various embodiments of the present disclosure, functional modules may be integrated into one processing module, or each module may exist physically separately, or two or more modules may be integrated into one module. The above-mentioned integrated modules may be implemented in the form of hardware or in the form of software functional modules.

If the integrated modules are implemented in the form of software functional modules and sold or used as independent products, they may be stored in a computer-readable storage medium. Based on such understanding, the technical solution of the present disclosure, in essence, or the part contributing to the prior art, or all or part of the technical solution, may be embodied in the form of a software product. The computer software product is stored in a storage medium and includes several instructions for causing a computer device (such as a personal computer, a server, or a network device) to perform all or part of the steps of the methods described in the various embodiments of the present disclosure. The aforementioned storage medium includes various media that can store program codes, such as a USB flash drive, a removable hard disk, a read-only memory (ROM), a random access memory (RAM), a magnetic disk, or an optical disk.

The embodiments described above are merely illustrative of the present disclosure to enable those skilled in the art to understand or implement the present disclosure, instead of limiting the scope of the present disclosure. Although the disclosure has been described in detail with reference to the above embodiments, various variations, replacements and modifications can still be made by those skilled in the art to the technical solutions recited in the above embodiments. It should be understood that those modifications, variations and replacements made without departing from the spirit of the disclosure shall fall within the scope of the disclosure defined by the appended claims.

What is claimed is:

1. A ranked successive detection and decoding (R-SDD) method based on Sparse Code Multiple Access (SCMA), comprising:
in response to receiving a received signal superimposed by transmissions from a plurality of users, successively performing, based on the received signal and an initialized posteriori log-likelihood ratio of each user, message passing iterative detection to determine a first priori log-likelihood ratio, and performing an external iteration of decoding and decoding verification according to a real-time confidence order corresponding to the first priori log-likelihood ratio, so as to determine a first posteriori log-likelihood ratio of each user and update as a successfully decoded user or an unsuccessfully decoded user, and update an external iteration count;
determining whether there is the unsuccessfully decoded user and whether the external iteration count reaches an external iteration threshold;
if there is the unsuccessfully decoded user and the external iteration count does not reach the external iteration threshold, successively performing an external iteration for each unsuccessfully decoded user using the received signal and each first posteriori log-likelihood ratio, so as to determine a second posteriori log-likelihood ratio of each unsuccessfully decoded user, update as the successfully decoded user or the unsuccessfully decoded user, and update the external iteration count; and
when it is determined that there is no unsuccessfully decoded user or that the external iteration count reaches the external iteration threshold, outputting a decoded bit sequence consisting of decoded bits of each user.

2. The R-SDD method of claim 1, wherein the step of “in response to receiving a received signal superimposed by transmissions from a plurality of users, successively performing, based on the received signal and an initialized posteriori log-likelihood ratio of each user, message passing iterative detection to determine a first priori log-likelihood ratio, and performing an external iteration of decoding and decoding verification according to a real-time confidence order corresponding to the first priori log-likelihood ratio, so as to determine a first posteriori log-likelihood ratio of each user and update as a successfully decoded user or an unsuccessfully decoded user, and update an external iteration count” comprises:
in response to receiving the received signal superimposed by transmissions from the plurality of users, determining the initialized posteriori log-likelihood ratio for each user;
performing the message passing iterative detection using the received signal and each initialized posteriori log-likelihood ratio, and outputting the first priori log-likelihood ratio for each user;
calculating the real-time confidence level based on each first priori log-likelihood ratio, and sorting to determine the real-time confidence order;
selecting, according to the real-time confidence order, a user with a highest confidence level as a to-be-decoded user;
performing decoding based on a first priori log-likelihood ratio of the to-be-decoded user, and determining a corresponding first posteriori log-likelihood ratio;
performing decoding verification using the first posteriori log-likelihood ratio, and determining the to-be-decoded user as the successfully decoded user or the unsuccessfully decoded user according to a determination of whether decoding is successful;
performing message passing iterative detection for all users using each initialized posteriori log-likelihood ratio that has been updated correspondingly with a current first posteriori log-likelihood ratio, and determining a new real-time confidence order for undecoded users; and
selecting, according to the new real-time confidence order, a user with a highest confidence level as a new to-be-decoded user for decoding, until the first posteriori log-likelihood ratio for each user is determined, each user is updated as a successfully decoded user or an unsuccessfully decoded user, and the external iteration count is updated.

3. The R-SDD method of claim 2, wherein the step of “performing the message passing iterative detection using each initialized posteriori log-likelihood ratio, and outputting the first priori log-likelihood ratio for each user” comprises:
performing message iterative transmission based on each initialized posteriori log-likelihood ratio, and determining a priori log-likelihood ratio for any user in any current transmission round;
if the current transmission round is 1, calculating an average absolute change using the initialized posteriori log-likelihood ratio of any user and the priori log-likelihood ratio at the current transmission round;
if the current transmission round is greater than 1, calculating an average absolute change using the priori log-likelihood ratio of any user at a previous transmission round and the priori log-likelihood ratio at the current transmission round; and
when the average absolute change is less than a change threshold or the current transmission round reaches a transmission round threshold, outputting the priori log-likelihood ratio at the current transmission round as the first priori log-likelihood ratio of any user.

4. The R-SDD method of claim 2, wherein the step of “performing decoding verification using the first posteriori log-likelihood ratio, and determining the to-be-decoded user as the successfully decoded user or the unsuccessfully decoded user according to a determination of whether decoding is successful” comprises:
performing the decoding verification using a hard decision result of the first posteriori log-likelihood ratio of the to-be-decoded user;
if the decoding verification is passed, determining the to-be-decoded user as the successfully decoded user, and using a corresponding hard decision result as a decoded bit; and
if there is a hard decision result that does not pass the decoding verification, determining the to-be-decoded user as the unsuccessfully decoded user.

5. The R-SDD method of claim 1, wherein the real-time confidence level is an average mutual information based on the priori log-likelihood ratio.

6. A R-SDD receiver based on SCMA, comprising:
an SCMA detector;
a channel decoder; and
a decoding order controller;
wherein the SCMA detector is configured to perform, based on a received signal superimposed by transmissions from a plurality of users and an initialized posteriori log-likelihood ratio of each user or a first posteriori log-likelihood ratio of each user, message passing iterative detection for each user or for each unsuccessfully decoded user, and correspondingly determine a first priori log-likelihood ratio for each user or a second priori log-likelihood ratio for each unsuccessfully decoded user;
the channel decoder is configured to perform decoding and decoding verification based on each first priori log-likelihood ratio or each second priori log-likelihood ratio; determine the first posteriori log-likelihood ratio for each user or the second posteriori log-likelihood ratio for each unsuccessfully decoded user; update and determine a successfully decoded user or an unsuccessfully decoded user, update an external iteration count according to the first posteriori log-likelihood ratio or the second posteriori log-likelihood ratio; and determine whether there is the unsuccessfully decoded user and whether the external iteration count reaches an external iteration threshold; and when it is determined that there is no unsuccessfully decoded user or that the external iteration count reaches the external iteration threshold, output a decoded bit sequence consisting of decoded bits of each user; and
the decoding order controller is configured to determine a real-time confidence order using a real-time confidence level corresponding to each first priori log-likelihood ratio; or, if there is the unsuccessfully decoded user and the external iteration count does not reach the external iteration threshold, determine a real-time confidence order using a real-time confidence level corresponding to each second priori log-likelihood ratio of each unsuccessfully decoded user; and control, according to the real-time confidence order, the SCMA detector and the channel decoder to successively perform external iterations of message passing iterative detection, decoding, and decoding verification.

7. A SCMA system, comprising:
a transmitter; and
the R-SDD receiver of claim 6;
wherein the transmitter is configured to encode, map, superimpose, and transmit information bit sequences of the plurality of users to the R-SDD receiver;
the R-SDD receiver is configured to receive the received signal transmitted by the transmitter and decode to output the decoded bit sequence.

8. A computer device, comprising:
a memory; and
a processor;
wherein the memory is configured to store a computer program; and the computer program is configured, when executed by a processor, to cause the processor to perform the R-SDD method of claim 1.

9. A computer-readable storage medium having a computer program/instruction, wherein the computer program/instruction, when executed by a processor, to cause the processor to implement the R-SDD method of claim 1.

10. A computer program product, comprising:
a computer program/instruction;
wherein the computer program/instruction, when executed by a processor, to cause the processor to implement the R-SDD method of claim 1.
